(19) United States
(12) Patent Application Publication
(10) Pub. No.: US 2007/0175610 A1
(43) Pub. Date: Aug. 2, 2007

(54) Heat dissipating device

(76) Inventor: Yun-Yu Yeh, Tainan Hsien (TW)

Correspondence Address: OSTROLENK FABER GERB & SOFFEN, 1180 AVENUE OF THE AMERICAS, NEW YORK, NY, 100368403, US

(21) Appl. No.: 11/342,416

(22) Filed: Jan. 30, 2006

(51) Int. Cl. H05K 7/20

(52) U.S. Cl. 165/80.4; 361/699; 165/104.33

(57) ABSTRACT

A heat dissipating device includes: a heat sink including a container adapted to be in contact with a heat generating source and adapted to store a coolant therein; a radiator unit disposed above the container and in fluid communication with the container; a fan unit disposed above the container and confronting the radiator unit; and a driving unit connected to the container for circulating the coolant through the container and the radiator unit.

### BACKGROUND OF THE INVENTION

1. Field of the Invention

This invention relates to a heat dissipating device, more particularly to a heat dissipating device for dissipating heat generated by electronic elements in a computer.

2. Description of the Related Art

As operating speed of a central processing unit (CPU) of a computer keeps getting higher, more attention is being paid to dissipation of heat generated by CPU and other elements in the computer. In order to efficiently dissipate heat in the computer, a Balanced Technology eXtended (BTX) system has been proposed. In this system, heat is expelled at higher efficiency by changing the arrangement of CPU, a fan unit, etc., thereby changing the direction of heated air flow to the external environment. However, rearrangement of the elements and altering of the flow direction in the computer is insufficient for heat dissipation of future generation CPUs with higher operating speeds. Therefore, there is still a need in the art to provide a heat dissipating device with higher heat dissipating efficiency so as to cope with future developments in the industry.

### SUMMARY OF THE INVENTION

Therefore, the object of the present invention is to provide a heat dissipating device that has a higher heat dissipating efficiency as compared to the prior art.

According to this invention, a heat dissipating device comprises: a heat sink including a container adapted to be in contact with a heat generating source and adapted to store a coolant therein; a radiator unit disposed above the container and in fluid communication with the container; a fan unit disposed above the container and confronting the radiator unit; and a driving unit connected to the container for circulating the coolant through the container and the radiator unit.

### BRIEF DESCRIPTION OF THE DRAWINGS

Other features and advantages of the present invention will become apparent in the following detailed description of the preferred embodiments of this invention, with reference to the accompanying drawings, in which:

FIG. 1 is an assembled perspective view of the first preferred embodiment of a heat dissipating device according to this invention;

FIG. 2 is an exploded perspective view of the first preferred embodiment;

FIG. 3 is a partly sectional schematic view of the first preferred embodiment;

FIG. 4 is a partly sectional schematic view of a radiator unit of the first preferred embodiment;

FIG. 5 is a schematic view of the second preferred embodiment of a heat dissipating device according to this invention;

FIG. 6 is a partly sectional schematic view of the third preferred embodiment of a heat dissipating device according to this invention;

FIG. 7 is a partly sectional schematic view of the fourth preferred embodiment of a heat dissipating device according to this invention; and

FIG. 8 is a schematic view of the fifth preferred embodiment of a heat dissipating device according to this invention.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

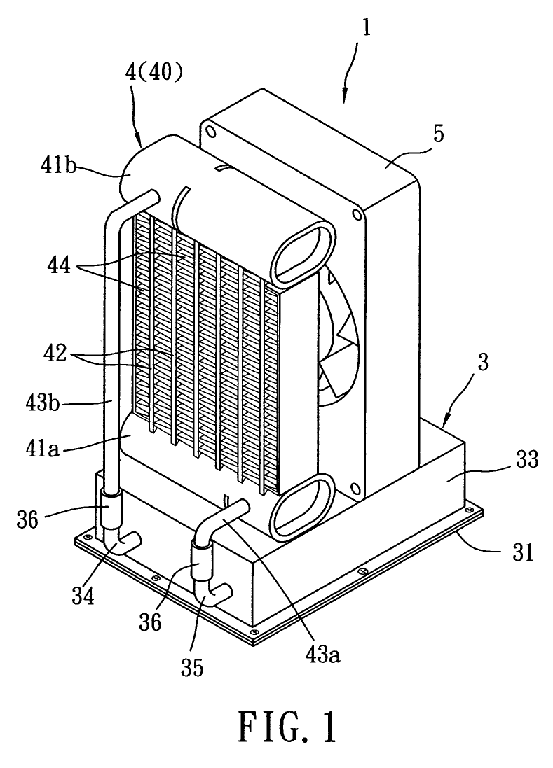

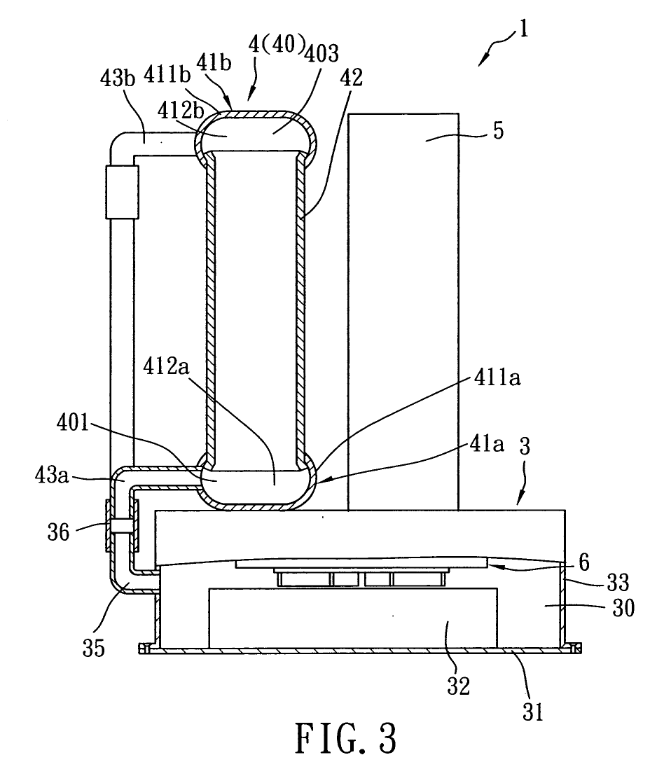

FIGS. 1 to 3 illustrate the first preferred embodiment of a heat dissipating device 1 according to the present invention. The heat dissipating device 1 includes: a heat sink 3 including a container 33; a radiator unit 4 disposed above the container 33 and in fluid communication with the container 33; a fan unit 5 disposed above the container 33 and confronting the radiator unit 4; and a driving unit 6 disposed in and connected to the container 33. The radiator unit 4 and the fan unit 5 are in direct contact with the container 33 in this embodiment.

The container 33 confines an inner space 30 adapted to store a coolant therein, and includes a heat conductive bottom plate 31 adapted to be in contact with a heat generating source, e.g., a CPU of a computer. The heat sink 3 further includes a plurality of heat dissipating fins 32 disposed in the container 33 and connected to the heat conductive bottom plate 31.

The radiator unit 4 in this preferred embodiment includes a first heat dissipating unit 40. The first heat dissipating unit 40 includes: a plurality of first tubes 42; a plurality of fins 44 disposed between and in contact with each two adjacent ones of the first tubes 42; a first casing 41a; and a second casing 41b.

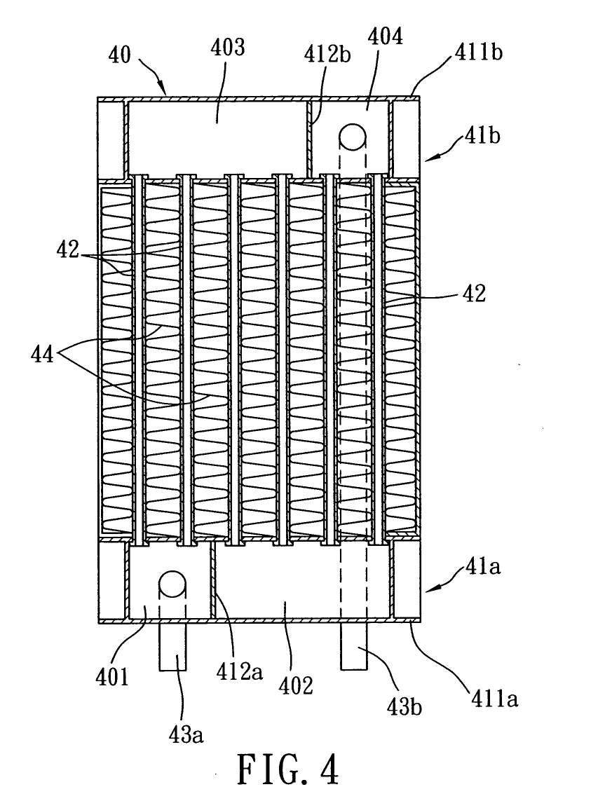

As shown in FIG. 4, the first casing 41a has a first inner wall 411a that defines a first inner space, and a first partitioning plate 412a that is sealingly connected to the first inner wall 411a of the first casing 41a so as to divide the first inner space into separated first and second chambers 401, 402. The second casing 41b has a second inner wall 411b that defines a second inner space, and a second partitioning plate 412b that is sealingly connected to the second inner wall 411b of the second casing 41b so as to divide the second inner space into separated third and fourth chambers 403, 404.

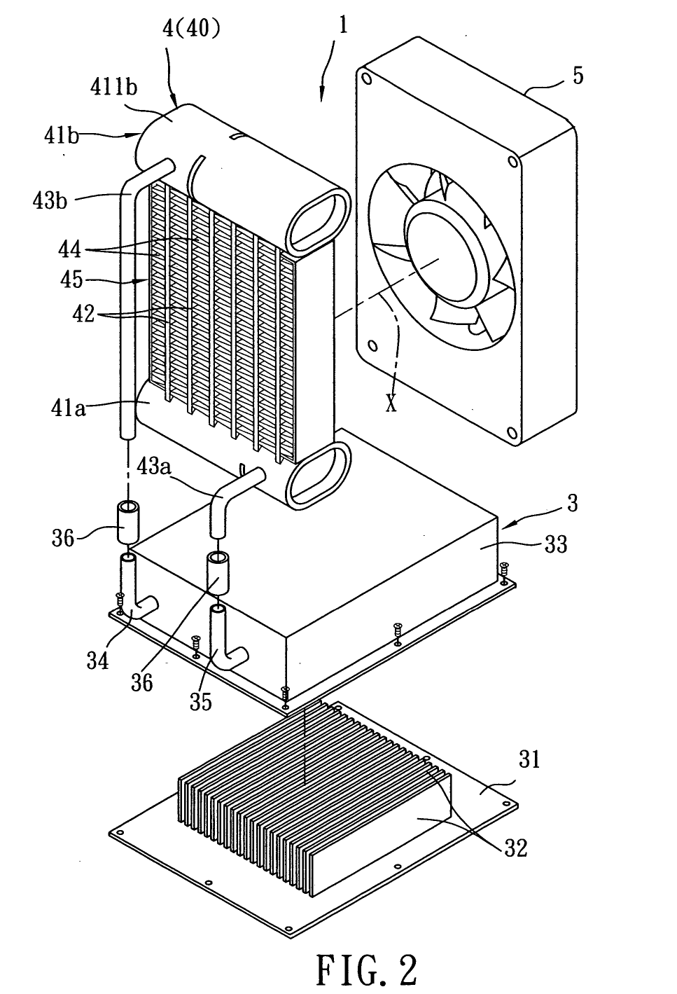

Preferably, as shown in FIG. 2, the container 33 includes a first conduit 34 and a second conduit 35. The first and second casings 41a, 41b are provided with coolant tubes 43a, 43b, respectively, and the coolant tubes 43a, 43b are connected to the second conduit 35 and the first conduit 34, respectively. In this embodiment, the first heat dissipating unit 40 further includes two sleeves 36 for connecting the coolant tubes 43a, 43b and the second conduit 35 and the first conduit 34, respectively.

The first chamber 401 is in fluid communication with the container 33 through the coolant tube 43a and the second conduit 35. The fourth chamber 404 is in fluid communication with the container 33 through the coolant tube 43b and the first conduit 34. The first chamber 401 of the first casing 41a is in fluid communication with the third chamber 403 of the second casing 41b through a portion of the first tubes 42. The third chamber 403 of the second casing 41b is in fluid communication with the fourth chamber 404 of the second casing 41b through the remaining portion of the first tubes 42 and the second chamber 402 of the first casing 41a.

In this embodiment, as shown in FIG. 4, there are two of the first tubes 42 interconnecting the first chamber 401 and the third chamber 403. There are another two of the first tubes 42 interconnecting the third chamber 403 and the second chamber 403. The remaining two of the first tubes 42 interconnect the second chamber 402 and the fourth chamber 404.

Referring back to FIG. 2, the fins 44 of the first heat dissipating unit 40 cooperatively define a heat dissipating plane 45 that is perpendicular to the heat conductive bottom plate 31 of the container 33. The fan unit 5 defines a rotation axis (X) that is perpendicular to the heat dissipating plane 45.

In use, the heat generated by the CPU (not shown) is transferred to the fins 32 of the heat sink 3. The coolant (not shown) in the container 33 of the heat sink 3 absorbs heat from the fins 32 so as to carry the heat from the heat sink 3. The heated coolant enters the first chamber 401 by the driving force of the driving unit 6, then flows into the third chamber 403, the second chamber 402, and the fourth chamber 404 sequentially through the first tubes 42, and finally flows back to the container 33 of the heat sink 3 through the coolant tube 43b and the first conduit 34. As such, the heat generated by the CPU is expelled from the radiator unit 4. The fan unit 5 generates an air flow toward the radiator unit 4 so as to cool the radiator unit 4 as well as the region in the path of the air flow.

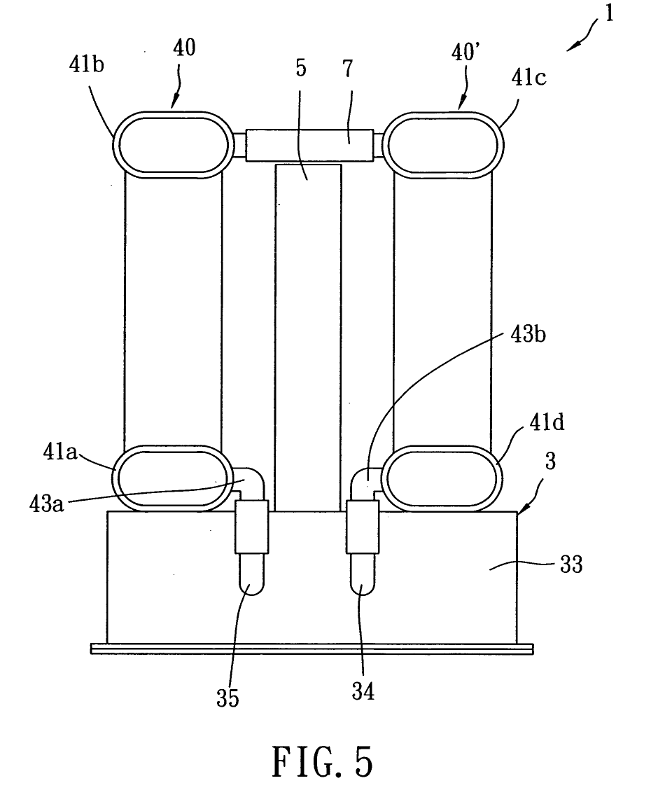

FIG. 5 illustrates the second preferred embodiment of a heat dissipating device 1 according to the present invention. The second preferred embodiment differs from the first preferred embodiment in that the radiator unit 4 further includes a second heat dissipating unit 40′ and a connecting tube 7. The second heat dissipating unit 40′ includes a plurality of second tubes (not shown), which have a structure similar to that of the first tubes 42, and third and fourth casings 41c, 41d, which are in fluid communication with each other through the second tubes. The structure and arrangement of the second heat dissipating unit 40′ are similar to those of the first heat dissipating unit 40.

The second casing 41b is in fluid communication with the third casing 41c through the connecting tube 7. The fourth casing 41d is in fluid communication with the container 33 of the heat sink 3 through the coolant tube 43b and the first conduit 34. The fan unit 5 is disposed between the first and second heat dissipating unit 40, 40′. Since the coolant flow inside the second heat dissipating unit 40′ is identical to that inside the first heat dissipating unit 40, a description of the same is not repeated herein.

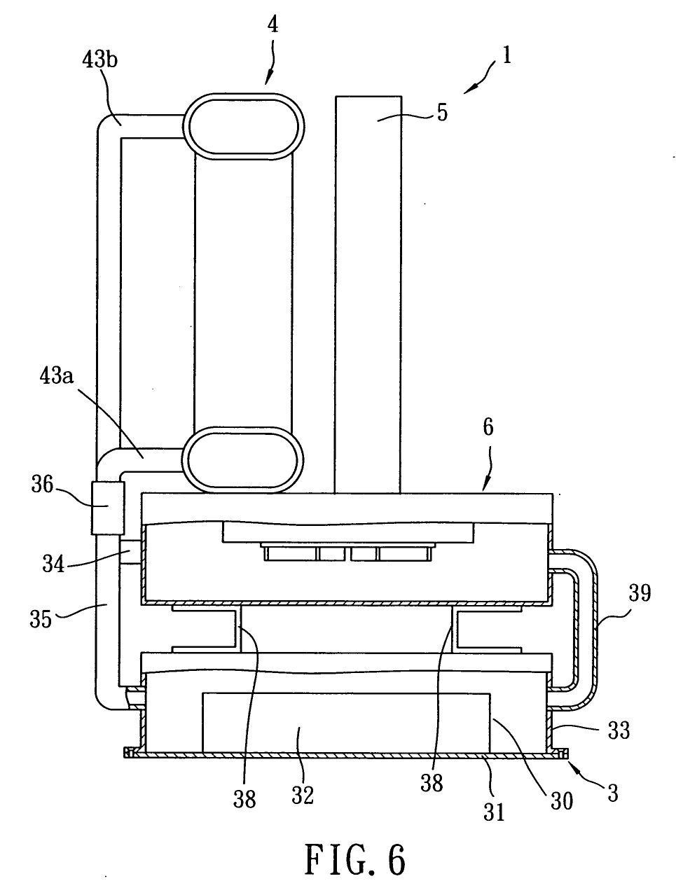

FIG. 6 shows the third preferred embodiment of a heat dissipating device 1 according to the present invention. In this embodiment, the driving unit 6 is disposed above and is spaced apart from the heat sink 3 by two spacers 38. The driving unit 6 is provided with a connecting tube 39 so as to connect to the container 33 of the heat sink 3. The radiator unit 4 and the fan unit 5 are disposed on and are in contact with the driving unit 6. The coolant conduit 34 is connected to the driving unit 6, whereas the coolant conduit 35 is connected to the container 33 of the heat sink 3. The coolant (not shown) absorbing heat from the fins 32 enters into the radiator unit 4 through the second conduit 35 and coolant tube 43a. Thereafter, the cooled coolant (not shown) flows to the driving unit 6 from the radiator unit 4 through the coolant tube 43b and the first conduit 34, and then flows back to the heat sink 3 through the connecting tube 39.

Alternatively, the spacers 38 can be dispensed with. That is, the driving unit 6 can be in direct contact with the container 33 of the heat sink 3.

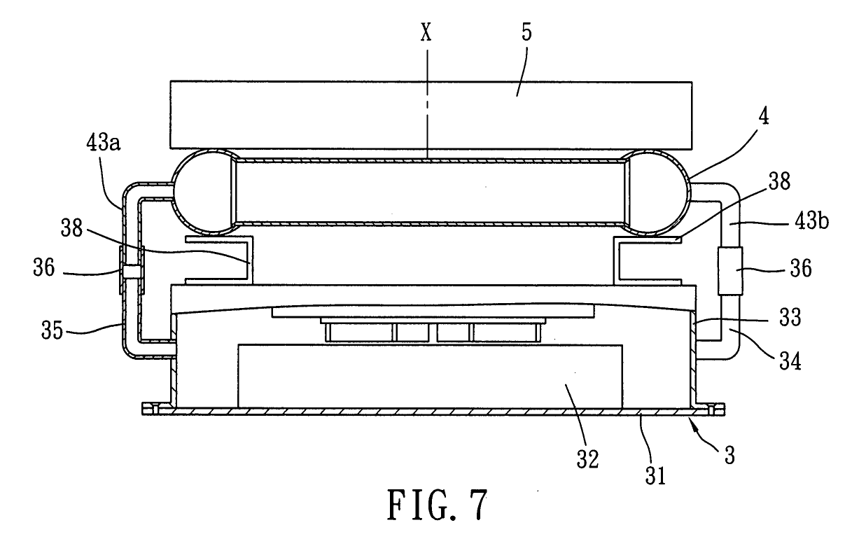

FIG. 7 illustrates the fourth preferred embodiment of a heat dissipating device 1 according to the present invention. The fourth preferred embodiment differs from the first preferred embodiment primarily in the arrangement of the radiator unit 4 and the fan unit 5.

As shown in FIG. 7, the radiator unit 4 and the fan unit 5 are disposed above the container 33 of the heat sink 3. The fan unit 5 is disposed on and is in contact with the radiator unit 4. The radiator unit 4 is spaced a part from the container 33 of the heat sink 3 by two spacers 38. The heat dissipating plane (not shown) of the radiator unit 4 is parallel to the heat conductive bottom plate 31 of the container 33. The rotation axis (X) of the fan unit 5 is perpendicular to the heat dissipating plane. As a consequence, an air flow generated by the fan unit 5 passes through the fins (not shown) of the heat dissipating unit 40 to the container 33 of the heat sink 3 so as to cool the radiator unit 4 as well as the surrounding area around the CPU of the computer.

Alternatively, the spacers 38 can be dispensed with. That is, the radiator unit 4 can be in direct contact with the container 33 of the heat sink 3.

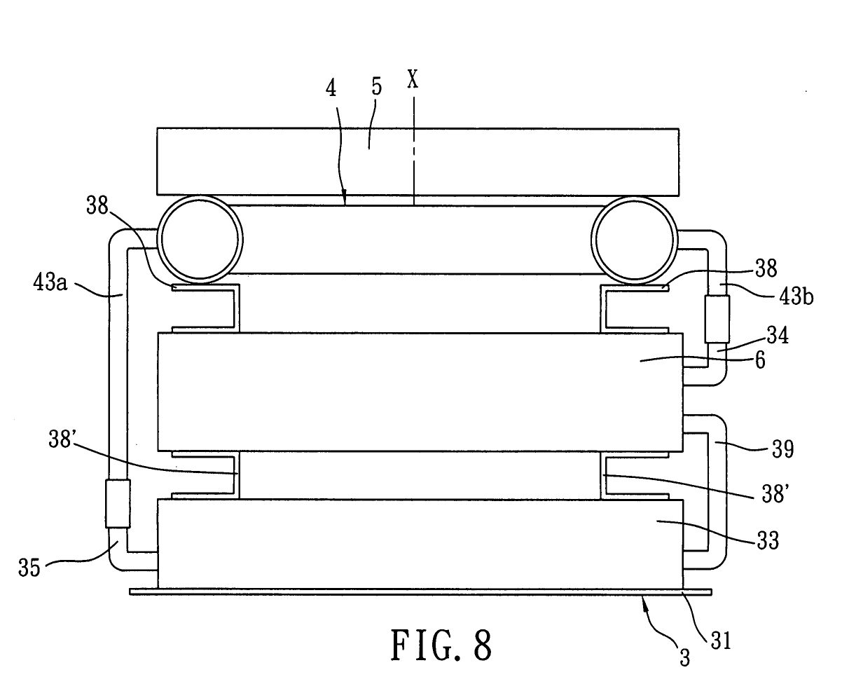

FIG. 8 illustrates the fifth preferred embodiment of a heat dissipating device 1 according to the present invention, which is a modification of the third preferred embodiment shown in FIG. 6. The fifth preferred embodiment differs from the third preferred embodiment primarily in the arrangement of the radiator unit 4 and the fan unit 5.

As shown in FIG. 8, the radiator unit 4 and the fan unit 5 are disposed above the driving unit 6. The fan unit 5 is disposed on and is in contact with the radiator unit 4. The radiator unit 4 is spaced apart from the driving unit 6 by two spacers 38. The driving unit 6 is spaced apart from the container 33 of the heat sink 3 by two spacers 38′. The heat dissipating plane (not shown) of the radiator unit 4 is parallel to the heat conductive bottom plate 31 of the container 33. The rotation axis (X) of the fan unit 5 is perpendicular to the heat dissipating plane. As a consequence, an air flow generated by the fan unit 5 passes through the fins (not shown) of the heat dissipating unit 40 to the driving unit 6 so as to cool the radiator unit 4 as well as the surrounding area around the CPU of the computer.

Alternatively, the spacers 38, 38′ can be dispensed with. That is, the driving unit 6 can be in direct contact with the container 33 of the heat sink 3, and the radiator unit 4 can be in direct contact with the driving unit 6.

It should be noted herein that the first to third preferred embodiments, in which the heat dissipating plane 45 is perpendicular to the heat conductive bottom plate 31 of the container 33 and the rotation axis (X) is perpendicular to the heat dissipating plane 45, can be applied to the BTX system, whereas the fourth and fifth preferred embodiments, in which the heat dissipating plane 45 is parallel to the heat conductive bottom plate 31 of the container 33 and the rotation axis (X) is perpendicular to the heat dissipating plane 45, can be applied to the conventional Advanced Technology extended (ATX) system.

According to this invention, with the inclusion of the radiator unit 4 in which the coolant flows in a meandering manner, and the fan unit 5 which generates an air flow in a specific direction, the efficiency of heat dissipation in this invention is improved. Moreover, the first tubes 42, the second tubes, and the fins 44 of the first and second heat dissipating units 40, 40′ provide a large surface area for heat dissipation, thereby resulting in an increase in the efficiency of heat dissipation.

While the present invention has been described in connection with what is considered the most practical and preferred embodiments, it is understood that this invention is not limited to the disclosed embodiments but is intended to cover various arrangements included within the spirit and scope of the broadest interpretation and equivalent arrangements.

What is claimed is:

1. A heat dissipating device comprising:
a heat sink including a container adapted to be in contact with a heat generating source and adapted to store a coolant therein;
a radiator unit disposed above said container and in fluid communication with said container;
a fan unit disposed above said container and confronting said radiator unit; and
a driving unit connected to said container for circulating the coolant through said container and said radiator unit.

2. The heat dissipating device of claim 1, wherein said container includes a heat conductive bottom plate, said heat sink further including a plurality of heat dissipating fins disposed in said container and connected to said heat conductive bottom plate.

3. The heat dissipating device of claim 2, wherein said radiator unit includes a first heat dissipating unit, said first heat dissipating unit including:
a plurality of first tubes;
a plurality of fins disposed between and in contact with each two adjacent ones of said first tubes;
a first casing having first and second chambers that are separated from each other, said first chamber being in fluid communication with said container; and
a second casing having third and fourth chambers that are separated from each other, said fourth chamber being in fluid communication with said container;
wherein said first chamber of said first casing is in fluid communication with said third chamber of said second casing through a portion of said first tubes, and said third chamber of said second casing is in fluid communication with said fourth chamber of said second casing through the remaining portion of said first tubes and said second chamber of said first casing.

4. The heat dissipating device of claim 3, wherein said first casing has a first inner wall that defines a first inner space, and a first partitioning plate that is sealingly connected to said first inner wall of said first casing so as to divide said first inner space into said first and second chambers, said second casing having a second inner wall that defines a second inner space, and a second partitioning plate that is sealingly connected to said second inner wall of said second casing so as to divide said second inner space into said third and fourth chambers.

5. The heat dissipating device of claim 3, wherein said fins of said first heat dissipating unit cooperatively define a heat dissipating plane that is perpendicular to said heat conductive bottom plate of said container, said fan unit defining a rotation axis that is perpendicular to said heat dissipating plane.

6. The heat dissipating device of claim 3, wherein said radiator unit further includes a second heat dissipating unit and a connecting tube, said second heat dissipating unit including a plurality of second tubes and third and fourth casings, said third and fourth casings being in fluid communication with each other through said second tubes, said third casing of said second heat dissipating unit being in fluid communication with said second casing of said first heat dissipating unit through said connecting tube.

7. The heat dissipating device of claim 5, wherein said driving unit is disposed in said container, said fan unit and said radiator unit being in direct contact with said container.

8. The heat dissipating device of claim 6, wherein said driving unit is disposed in said container, said fan unit and said radiator unit being in direct contact with said container.

9. The heat dissipating device of claim 5, wherein said driving unit is disposed above and is spaced apart from said container, said fan unit and said radiator unit being in contact with said driving unit, said radiator unit being connected to said driving unit.

10. The heat dissipating device of claim 3, wherein said fins of said first heat dissipating unit cooperatively define a heat dissipating plane that is parallel to said heat conductive bottom plate of said container, said fan unit defining a rotation axis that is perpendicular to said heat dissipating plane.

11. The heat dissipating device of claim 10, wherein said driving unit is disposed in said container, said fan unit and said radiator unit being disposed above and being spaced apart from said container.

12. The heat dissipating device of claim 10, wherein said driving unit is disposed above and is spaced apart from said container, said fan unit and said radiator unit being disposed above and being spaced apart from said driving unit.

13. The heat dissipating device of claim 12, wherein said driving unit is connected to said container and said radiator unit.
